(19) United States
(12) Patent Application Publication
(10) Pub. No.: US 2018/0067392 A1
(43) Pub. Date: Mar. 8, 2018

(54) IMPRINT APPARATUS AND METHOD OF MANUFACTURING ARTICLE

(71) Applicant: CANON KABUSHIKI KAISHA, Tokyo (JP)

(72) Inventor: Naoki Murasato, Utsunomiya-shi (JP)

(21) Appl. No.: 15/689,633

(22) Filed: Aug. 29, 2017

(30) Foreign Application Priority Data
Sep. 5, 2016 (JP) 2016-173125

(51) Int. Cl. G03F 7/00; G03F 7/20

(52) U.S. Cl. CPC G03F 7/0002; G03F 7/2051

(57) ABSTRACT

An imprint apparatus performs an imprint process of bringing a mold into contact with an imprint material on a substrate and curing the imprint material by light irradiation. The apparatus includes a light source which emits light to irradiate the imprint material that is in contact with the mold, a light blocking portion which defines an irradiation region of the light emitted by the light source, a driver which drives the light blocking portion, an image capture which has a field of view capable of capturing a region irradiated with the light emitted by the light source, and a controller which generates, based on an image of the mold provided from the image capture, controls information which controls driving of the light blocking portion by the driver.

### BACKGROUND OF THE INVENTION

### Field of the Invention

The present invention relates to an imprint apparatus and a method of manufacturing an article.

### Description of the Related Art

In an optical imprint technique of manufacturing an article such as a semiconductor device, a mold (can also be referred to as a template) is brought into contact with an imprint material arranged on a substrate, and the imprint material is cured by irradiating the imprint material with light. Consequently, a pattern formed in the mold is transferred to the imprint material, and the pattern by the imprint material is formed on the substrate.

Japanese Patent Laid-Open No. 2009-212449 describes an imprint apparatus which includes, in order to define a region irradiated with ultraviolet light from a light source, a light blocking member which blocks the ultraviolet light from the light source and a light blocking member moving mechanism which moves the light blocking member. However, Japanese Patent Laid-Open No. 2009-212449 does not describe a mechanism or method of positioning the light blocking member accurately.

As one of methods of improving productivity, a method of bringing a mold into contact with an imprint material in each of a plurality of shot regions on a substrate where the imprint material is arranged to cure the imprint material after the imprint material is arranged on all, or two or more shot regions is examined. As another method of improving productivity, a method of arranging a spread accelerator on all, or two or more shot regions of the plurality of shot regions on the substrate, and then arranging the imprint material on the spread accelerator when an imprint process is performed on each shot region is examined. The spread accelerator accelerates the spread of the imprint material when the mold is brought into contact with the imprint material and/or accelerates filling, with the imprint material, of a concave portion that forms the pattern of the mold. The spread accelerator can be arranged on the substrate outside an imprint apparatus or in the imprint apparatus.

In the above-described method, if an outer region of a shot region where a pattern is to be formed is irradiated with curing light when the pattern is formed by the imprint material on each shot region, the imprint material in the outer region can be cured, and the spread accelerator can be deteriorated. It is therefore necessary to define an irradiation region irradiated with the curing light accurately.

### SUMMARY OF THE INVENTION

The present invention provides a technique advantageous in defining an irradiation region irradiated with light from a light source at high precision.

One of aspects of the present invention provides an imprint apparatus which performs an imprint process of bringing a mold into contact with an imprint material on a substrate and curing the imprint material by light irradiation, the apparatus comprising: a light source configured to emit light to irradiate the imprint material that is in contact with the mold; a light blocking portion configured to define an irradiation region of the light emitted by the light source; a driver configured to drive the light blocking portion; an image capture having a field of view capable of capturing a region irradiated with the light emitted by the light source; and a controller configured to generate, based on an image of the mold provided from the image capture, control information which controls driving of the light blocking portion by the driver.

Further features of the present invention will become apparent from the following description of exemplary embodiments with reference to the attached drawings.

### BRIEF DESCRIPTION OF THE DRAWINGS

FIG. 1 is a view schematically showing the arrangement of an imprint apparatus according to the first embodiment of the present invention;

FIG. 2 is a view showing an arrangement example of a mold;

FIG. 3 is a flowchart showing a process for generating control information which controls driving of a light blocking portion by a driver;

FIG. 4 is a view exemplarily and schematically showing the relationship between a target irradiation region and an irradiation region irradiated with light from a light source;

FIG. 5 is a view showing an arrangement example of the light blocking portion and the driver;

FIGS. 6A and 6B are views exemplarily showing an operation of forming a pattern on a substrate by the imprint apparatus;

FIGS. 7A and 7B are views exemplarily showing an operation of forming the pattern on the substrate by the imprint apparatus;

FIG. 8 is a view exemplarily showing an operation of forming the pattern on the substrate by the imprint apparatus;

FIG. 9 is a view showing a state of dummy irradiation and image capture;

FIG. 10 is a view exemplarily showing the order of an imprint process for a plurality of shot regions on the substrate;

FIG. 11 is a view schematically showing the arrangement of an imprint apparatus according to the second embodiment of the present invention;

FIG. 12 is a view schematically showing the arrangement of an imprint apparatus according to the third embodiment of the present invention;

FIG. 13 is a view schematically showing the arrangement of an imprint apparatus according to the fourth embodiment of the present invention;

FIG. 14 is a view showing another arrangement example of a light blocking portion and a driver; and

FIGS. 15A to 15F are views showing a method of manufacturing an article.

### DESCRIPTION OF THE EMBODIMENTS

An imprint apparatus and a method of manufacturing an article of the present invention will be described below through exemplary embodiments with reference to the accompanying drawings.

FIG. 1 schematically shows the arrangement of an imprint apparatus 100 according to the first embodiment of the present invention. The imprint apparatus 100 can be configured to perform an imprint process of bringing a mold M into contact with an imprint material on a substrate S and curing the imprint material by light irradiation. A curable composition (may also be referred to as an uncured resin) which is cured by receiving curing energy is used as the imprint material. For example, light (such as infrared light, visible rays, ultraviolet light, or the like) whose wavelength is selected from a range of 10 nm (inclusive) to 1 mm (inclusive) can be used as the curing energy. The curable composition can be a composition that is cured by light irradiation. A photo-curable composition that is cured by light irradiation contains at least a polymerizable compound and a photopolymerization initiator, and may further contain a non-polymerizable compound or solvent as needed. The non-polymerizable compound is at least a material selected from the group consisting of a sensitizer, a hydrogen donor, an internal mold release agent, a surfactant, an antioxidant, a polymer component, and the like. The imprint material can be arranged on the substrate in a droplet-like shape, or an island-like shape or a film-like shape formed by a plurality of droplets connected to each other. The viscosity (viscosity at 25° C.) of the imprint material can be set at, for example, 1 mPa·s (inclusive) to 100 mPa·s (inclusive). For example, glass, ceramics, a metal, a semiconductor, a resin, or the like can be used as a material of the substrate. A member made of a material different from that for the substrate may be provided on the surface of the substrate, as needed. For example, a silicon wafer, a compound semiconductor wafer, a silica glass plate, or the like is used as the substrate.

In this specification and the accompanying drawings, directions are shown in an X-Y-Z coordinate system in which a direction parallel to the surface of the substrate S forms an X-Y plane. Let an X direction, a Y direction, and a Z direction be the directions parallel to an X-axis, a Y-axis, and a Z-axis, respectively, in the X-Y-Z coordinate system. Let θX, θY, and θZ, respectively, be rotation about the X-axis, rotation about the Y-axis, and rotation about the Z-axis. Control or driving with regard to the X-axis, the Y-axis, and the Z-axis means control or driving with regard to the direction parallel to the X-axis, the direction parallel to the Y-axis, and the direction parallel to the Z-axis, respectively. Further, control or driving with regard to a θX-axis, a θY-axis, and a θZ-axis means control or driving with regard to rotation about an axis parallel to the X-axis, rotation about an axis parallel to the Y-axis, and rotation about an axis parallel to the Z-axis, respectively. A position is information that can be specified based on X-axis, Y-axis, and Z-axis coordinates. An attitude is information that can be specified by values on the θX-axis, the θY-axis, and the θZ-axis. Positioning means controlling the position and/or attitude. Alignment can include the control of the position and/or attitude of at least one of the substrate S and the mold M.

The imprint apparatus 100 includes a substrate driving mechanism SDM which positions the substrate S. The substrate driving mechanism SDM can include a coarse moving stage 3, a fine moving stage 2 supported by the coarse moving stage 3, a base frame 4 which supports the coarse moving stage 3, a coarse driving mechanism (not shown) which drives the coarse moving stage 3, and a fine moving mechanism (not shown) which drives the fine moving stage 2. The fine moving stage 2 includes a substrate holder (not shown) which holds the substrate S. The substrate driving mechanism SDM can be configured to drive the substrate S with respect to a plurality of axes (for example, three axes of the X-axis, the Y-axis, and the θZ-axis).

The imprint apparatus 100 includes a mold driving mechanism 24 which drives the mold M. The mold driving mechanism 24 can be configured to drive a mold holder 23 which holds the mold M. The mold driving mechanism 24 can be configured to drive the mold M with respect to a plurality of axes (for example, six axes of the X-axis, the Y-axis, the Z-axis, the θX-axis, the θY-axis, and the θZ-axis). The substrate driving mechanism SDM and the mold driving mechanism 24 form an alignment mechanism which drives the substrate S and the mold M so as to adjust the relative positions of the substrate S and the mold M. The imprint apparatus 100 can include a mold deformation mechanism 20 which deforms the mold M. The mold deformation mechanism 20 can be configured to deform the mold M by, for example, applying energy such as a force and/or heat to the mold M.

The imprint apparatus 100 includes, as components for curing the imprint material, a light source 6 which emits light to irradiate the imprint material in contact with the mold M, a light blocking portion 31 which defines the irradiation region of the light emitted by the light source 6, and a driver 32 which drives the light blocking portion 31. The light source 6 can include, for example, a halogen lamp which emits an i-line and/or g-line, or a mercury lamp. The imprint apparatus 100 can also include, as components for curing the imprint material in contact with the mold M, optical systems 21 and 22, and a mirror 16. The mirror 16 can be arranged so as to deflect the path of the light from the light source 6. The optical system 21 can be arranged between the mirror 16 and the mold holder 23. The optical system 22 can be arranged between the mirror 16 and the light source 6. The optical systems 21 and 22 can, respectively, be formed by a plurality of optical elements. The imprint apparatus 100 can additionally include a shutter for switching blocking and transmission of the light from the light source 6 when the light source 6 is turned on continuously in the imprint process for a plurality of shot regions or a plurality of substrates. The shutter may be incorporated into the light source 6.

The imprint apparatus 100 can include, as optical apparatuses, an alignment scope 11 and a camera 15 (which is an image capture or an image capture device). The alignment scope 11 can include an optical system and a camera. The alignment scope 11 is used to detect the relative positions of the alignment mark of the mold M and the alignment mark of the substrate S in alignment between the mold M and each shot region on the substrate S. The camera 15 can have a field of view capable of capturing a region irradiated with the light emitted by the light source 6 and be used to confirm the irradiation region of the light emitted by the light source 6. The camera 15 can also be used to observe a contact state between the mold M and the imprint material on the substrate S. However, another camera may be provided in order to observe the contact state between the mold M and the imprint material on the substrate S.

The camera 15 can be arranged so as to perform, via the mirror 16, image capture for confirming the irradiation region and image capture for observing the contact state. Note that the first mirror used when image capture for confirming the irradiation region is performed and the second mirror used when image capture for observing the contact state is performed may be provided as the mirrors 16. The first mirror can be configured to partially transmit light which is emitted by the light source 6, irradiates the mold M via the mirror 16, and returns from the side of the mold M. The second mirror can be configured to transmit light for observing the contact state while reflecting the light emitted by the light source 6.

The imprint apparatus 100 can additionally include a purge gas nozzle 12 and a purge gas tank 13. The purge gas nozzle 12 can be used to supply a purge gas to a space between the mold M and the substrate S. The purge gas can be a gas having the property of passing through the imprint material and the mold M. The purge gas can also be used to prevent curing of the imprint material from being inhibited by oxygen, that is, to prevent the imprint material from contacting oxygen. A gas which does not inhibit curing of the imprint material, such as a gas which contains at least one of helium gas, nitrogen gas, and a condensable gas (for example, pentafluoropropane (PFP)) can be used as the purge gas. The purge gas tank 13 supplies the purge gas to the purge gas nozzle 12.

The imprint apparatus 100 can additionally include a dispenser 7 (supplier) which supplies the imprint material onto the substrate S, a dispenser driving mechanism 10, and a tank 8. The dispenser 7 can be used in a mode of supplying the imprint material onto the substrate S in the imprint apparatus 100. The dispenser 7 is not used in a mode of supplying the imprint material to the substrate S outside the imprint apparatus 100. In the mode of supplying the imprint material onto the substrate S in the imprint apparatus 100, a spread accelerator can be supplied onto the substrate S in advance outside the imprint apparatus 100. The dispenser driving mechanism 10 moves the dispenser 7 to a designated position out of a plurality of positions. The plurality of positions can include, for example, a work position for supplying the imprint material onto the substrate S and a maintenance position for maintaining the dispenser 7. The tank 8 supplies the imprint material to the dispenser 7.

The imprint apparatus 100 can include a support base 14. The support base 14 can directly or indirectly support the mold driving mechanism 24, the light source 6, the light blocking portion 31, the driver 32, the alignment scope 11, the camera 15, the purge gas nozzle 12, the dispenser 7, the dispenser driving mechanism 10, and the like.

The imprint apparatus 100 additionally includes a controller 18. The controller 18 can be configured to generate, based on the image of the mold M provided from the camera 15, control information which controls driving of the light blocking portion 31 by the driver 32. The control information can be, for example, a command value provided for the driver 32 in order to operate the driver 32 so as to irradiate a target irradiation region with the light from the light source 6. Alternatively, the control information can be a correction value for generating a command value provided for the driver 32 in order to operate the driver 32 so as to irradiate the target irradiation region with the light from the light source 6. In this case, the command value that should be provided for the driver 32 can be generated by adding the correction value to an initial command value. Alternatively, the control information can be a correction table for generating a command value provided for the driver 32 in order to operate the driver 32 so as to irradiate the target irradiation region with the light from the light source 6. In this case, the command value that should be provided for the driver 32 can be generated by correcting the initial command value based on the correction table. The target irradiation region can be decided based on an image obtained by the camera 15 in a state in which the mold holder 23 holds the mold M.

In addition, the controller 18 can be configured to control the substrate driving mechanism SDM, the mold driving mechanism 24, the mold deformation mechanism 20, the mold holder 23, the light source 6, the alignment scope 11, the purge gas nozzle 12, the dispenser 7, the dispenser driving mechanism 10, and the like. The controller 18 can be formed by, for example, a PLD (an abbreviation for a Programmable Logic Device) such as an FPGA (an abbreviation for a Field Programmable Gate Array), an ASIC (an abbreviation for an Application Specific Integrated Circuit), a general-purpose computer into which programs are integrated, or a combination of all or some of these.

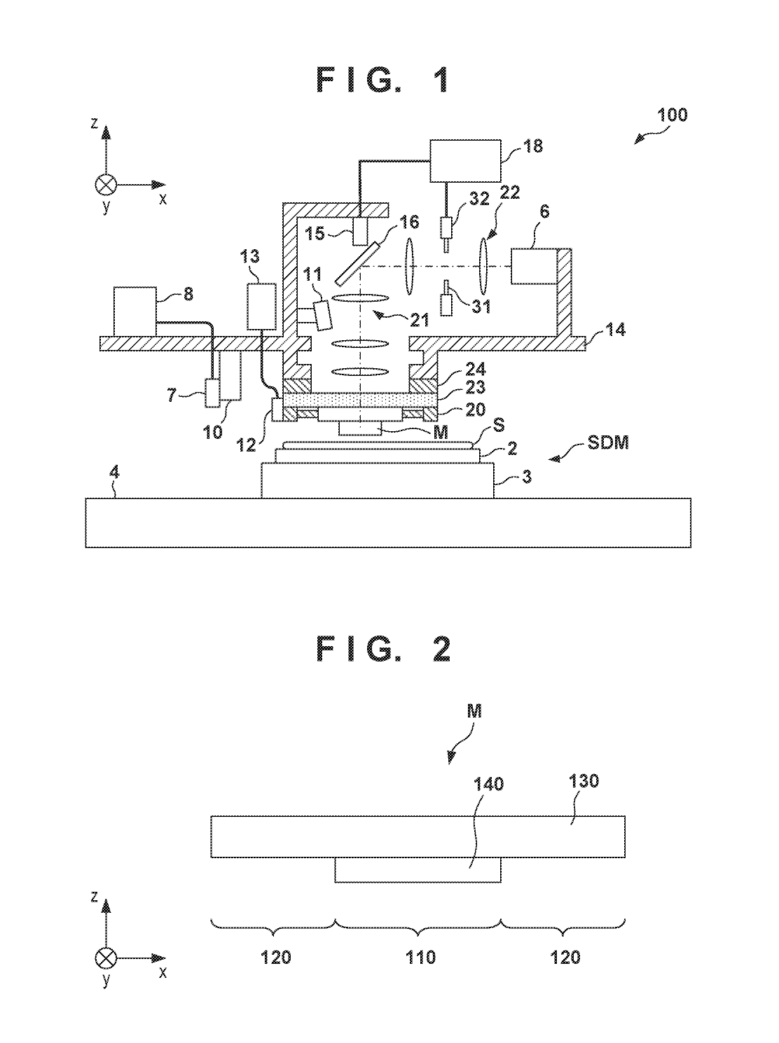

FIG. 2 shows an arrangement example of the mold M. The mold M can include a pattern region 110 in which a pattern that should be transferred to the imprint material on the substrate S is formed and peripheral region 120 which surrounds the pattern region 110. In another aspect, the mold M can include a support plate 130 and a mesa portion 140 protruding from the support plate 130. The pattern region 110 can be provided in the mesa portion 140. The outer edge of the pattern region 110 may be arranged inside the mesa portion 140 or may match the outer edge of the mesa portion 140. The aforementioned target irradiation region can be a predetermined region of the mold M, typically the pattern region 110.

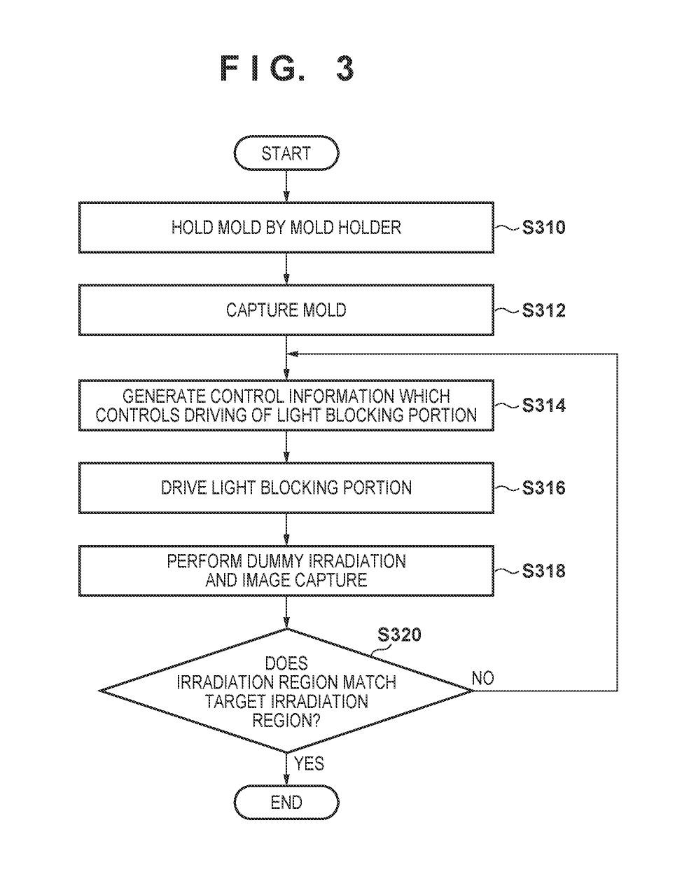

FIG. 3 shows a process for generating control information which controls driving of the light blocking portion 31 by the driver 32. The controller 18 controls this process. In step S310, the controller 18 controls a conveyance mechanism (not shown) so as to convey the mold M to the mold holder 23 and causes the mold holder 23 to hold the mold M. In step S312, the controller 18 causes the camera 15 to capture the mold M. With this image capture, an image including a predetermined region (for example, the pattern region 110) of the mold M as the target irradiation region is captured. The target irradiation region can change, by at least one of a manufacturing error of the mold M and a positioning error of the mold M with respect to the mold holder 23, each time the mold holder 23 holds the mold M.

In step S314, the controller 18 generates, based on the image captured in step S312, control information for controlling driving of the light blocking portion 31 by the driver 32 such that the irradiation region irradiated with light via the light blocking portion 31 by the light source 6 matches the target irradiation region. In step S316, the controller 18 controls driving of the light blocking portion 31 by the driver 32 based on the control information generated in step S314. If a driving error of the light blocking portion 31 by the driver 32 is small, driving of the light blocking portion 31 by the driver 32 is performed correctly by the above-described steps.

In step S318, the controller 18 turns on the light source 6 (alternatively, opens the shutter which switches blocking and transmission of the light from the light source 6), irradiates the mold M with the light from the light source 6, and causes the camera 15 to capture an image, as schematically shown in FIG. 9. Step S318 can be performed in a state in which, for example, the dummy substrate S is arranged on the fine moving stage 2. In step S320, the controller 18 judges, based on the image captured in step S318, whether the irradiation region irradiated with the light from the light source 6 matches the target irradiation region. If they match, the process shown in FIG. 3 is terminated. If they do not match, the process returns to step S314. If the process returns to step S314, the controller 18 regenerates, based on a shift between the target irradiation region and the irradiation region irradiated with the light of the light source 6 in step S314, the control information for controlling driving of the light blocking portion 31 by the driver 32. Steps S314 to S318 are thus repeated until the irradiation region irradiated with the light from the light source 6 matches the target irradiation region.

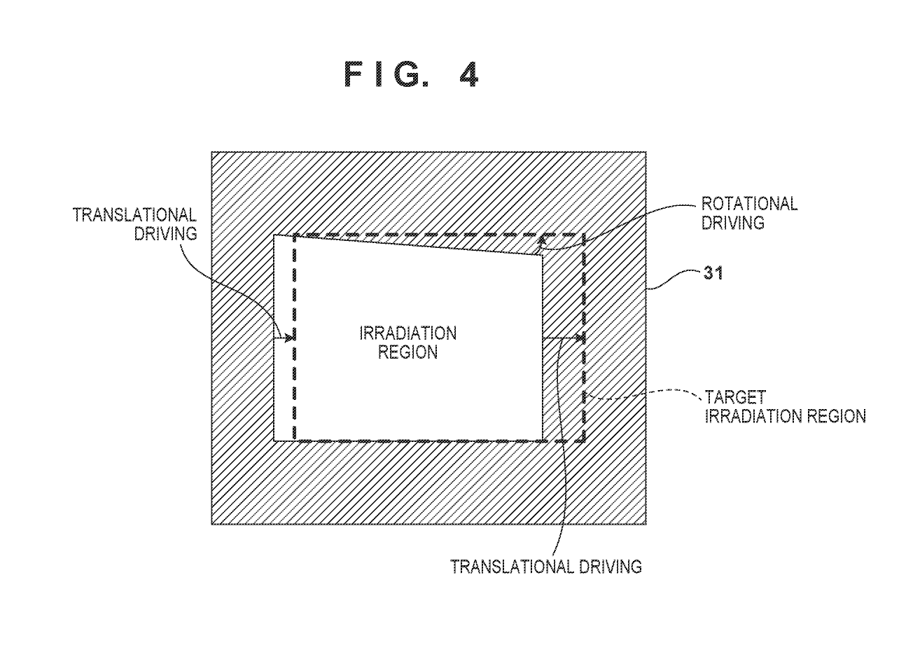

FIG. 4 exemplarily and schematically shows the relationship between the target irradiation region and the irradiation region irradiated with the light from the light source 6. Note that the irradiation region is defined by the light blocking portion 31. If the irradiation region does not match the target irradiation region, the driver 32 drives the light blocking portion 31. This driving can include translational driving and rotational driving of one or a plurality of light blocking blades that form the light blocking portion 31.

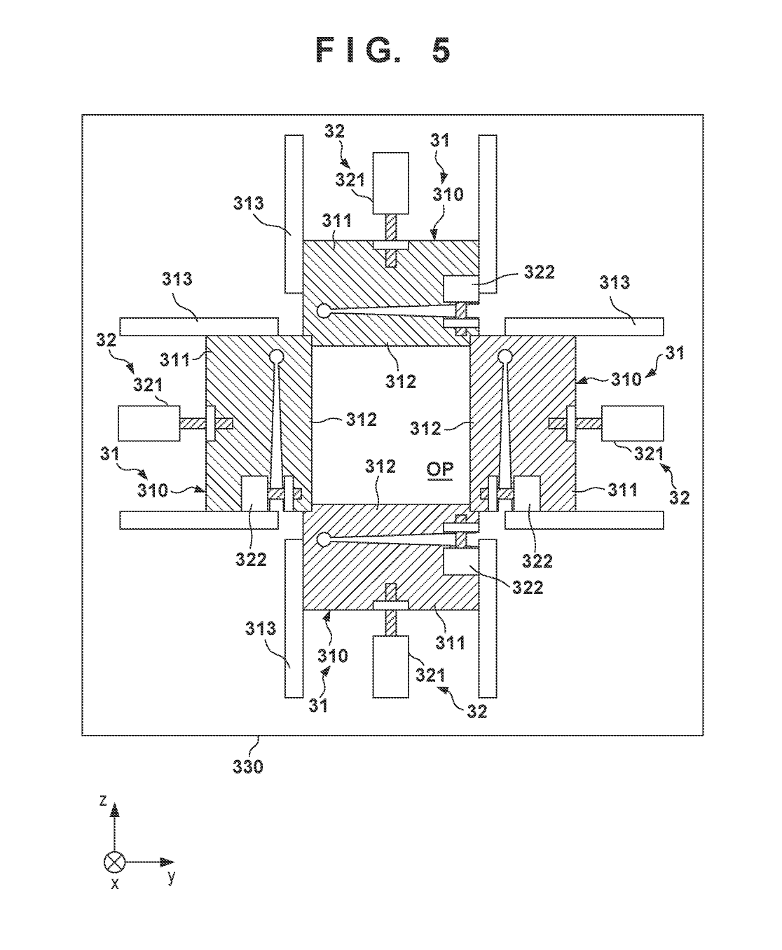

FIG. 5 shows an arrangement example of the light blocking portion 31 and the driver 32. The light blocking portion 31 can include a light blocking blade 310. The driver 32 can include a first actuator 321 which drives the light blocking blade 310 translationally and a second actuator 322 which drives the light blocking blade 310 rotationally. In a more concrete example, the light blocking portion 31 can include the four light blocking blades 310 which are, respectively, arranged so as to define four sides of a rectangular irradiation region. The driver 32 can include the four first actuators 321 which, respectively, drive the four light blocking blades 310 translationally and the four second actuators 322 which, respectively, drive the four light blocking blades 310 rotationally. A support plate 330 can support the light blocking blades 310, the first actuators 321, and the second actuators 322. The support plate 330 has an opening OP larger than an opening (an opening which defines the irradiation region) formed by the light blocking blades 310.

Each light blocking blade 310 can include a first portion 311 and a second portion 312 pivotably connected to the first portion 311. Each first actuator 321 can be arranged so as to drive the first portion 311 translationally. Each second actuator 322 can be arranged so as to drive the second portion 312 rotationally with respect to the first portion 311. The light blocking portion 31 can further include linear guides 313 which guide the first portion 311 so as to move it straight. The first actuators 321 and the second actuators 322 can be formed by, for example, rotation motors and ball screws. However, they may be formed by at least one of air cylinders, linear motors, piezoelectric devices, and the like. A sensor or a limit switch configured to confirm the position or the like of each light blocking blade 310 (the first portion 311 and the second portion 312) may also be provided.

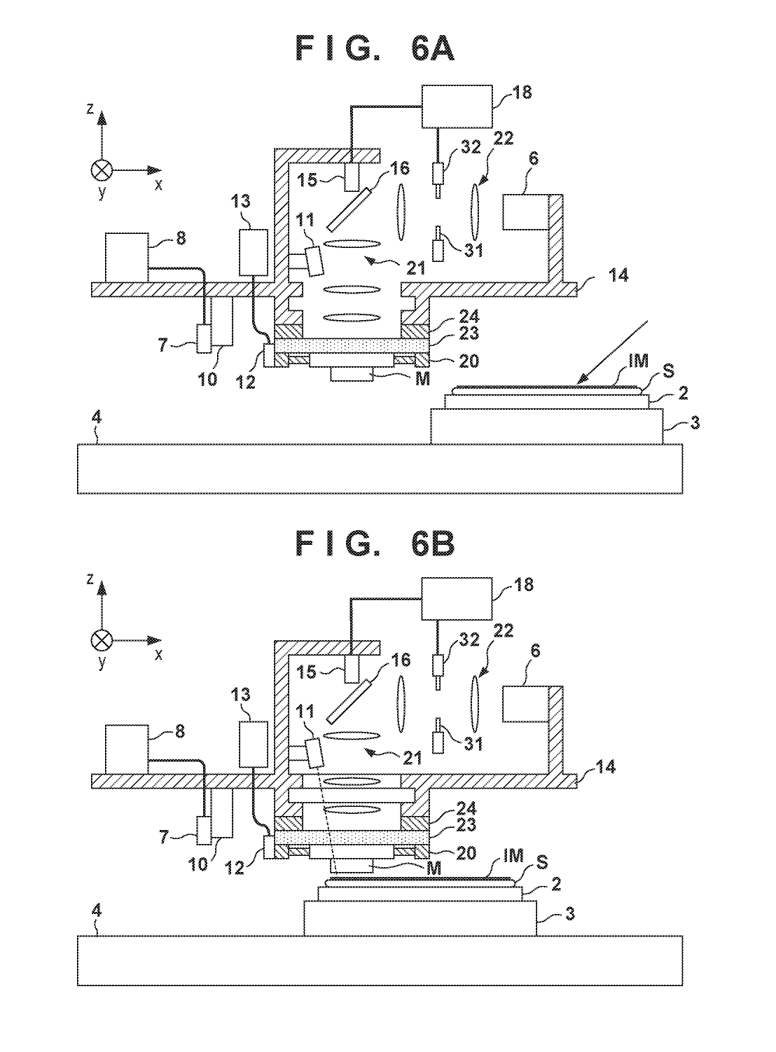

An operation of forming a pattern on the substrate S by the imprint apparatus 100 will exemplarily be described below with reference to FIGS. 6A, 6B, 7A, 7B, and 8. The controller 18 controls this operation. An example will be described here in which an imprint material IM is arranged on the substrate S in advance by an apparatus such as a spin coating apparatus arranged outside the imprint apparatus 100 with respect to the substrate S. First, in a step shown in FIG. 6A, the substrate S is supplied onto the fine moving stage 2. The imprint material IM is arranged on the substrate S.

Then, in a step shown in FIG. 6B, the fine moving stage 2 and the coarse moving stage 3 are driven such that the relative positions of the alignment mark of the mold M and an alignment mark for a shot region of the substrate S to be imprinted fall within the field of view of the alignment scope 11. Subsequently, the alignment scope 11 detects the relative positions, and alignment between the mold M and the shot region on the substrate S is performed based on the relative positions. Note that blowing of the purge gas from the purge gas nozzle 12 can be started between the step shown in FIG. 6A and the step shown in FIG. 6B.

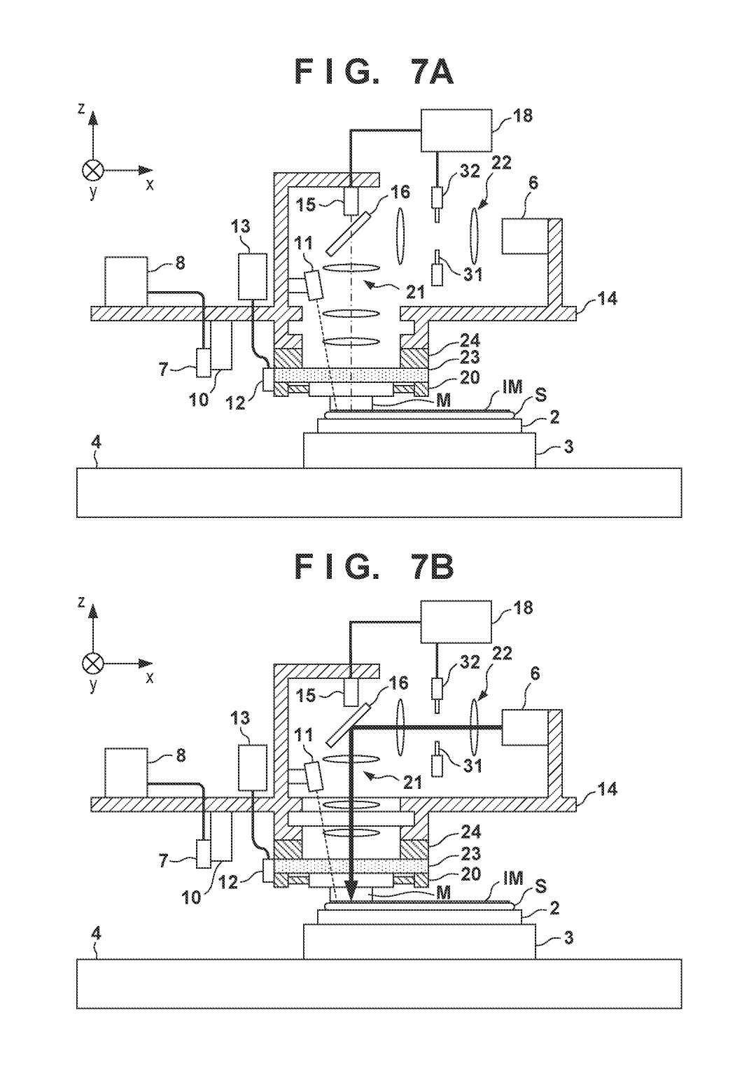

Then, in a step shown in FIG. 7A, the mold driving mechanism 24 drives the mold M downward, bringing the mold M into contact with the imprint material IM on the substrate S. At this time, the controller 18 can observe and grasp the contact state between the imprint material IM and the mold M based on the image captured by the camera 15. The controller 18 can control the light source 6 or the shutter so as to irradiate the imprint material IM with the light from the light source 6 after confirming that the imprint material IM and the entire pattern formation region of the mold M are brought into contact with each other. When the mold driving mechanism 24 drives the mold M downward, the alignment scope 11 continuously detects the relative positions, and alignment between the mold M and the shot region on the substrate S is performed continuously.

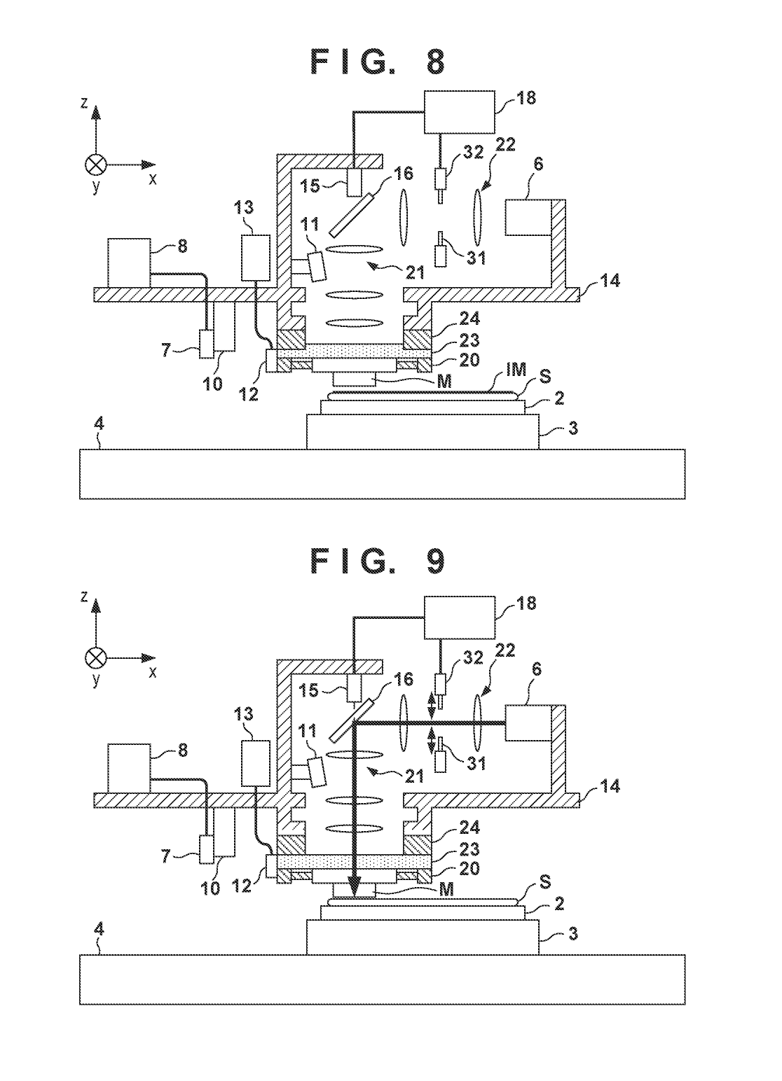

Then, in a step shown in FIG. 7B, the imprint material IM in the shot region to be imprinted is irradiated with the light from the light source 6 via the mold M, curing the imprint material IM. Consequently, the pattern of the mold M is transferred to the imprint material IM, and a pattern made of the imprint material IM is formed on the shot region of the substrate S to be imprinted. Note that if the target irradiation region differs for each shot region, the controller 18 controls the driver 32 based on control information according to the shot region to be imprinted and positions the light blocking portion 31 for each shot region. If the target irradiation region is the same for all the shot regions, the controller 18 controls the driver 32 based on the control information and positions the light blocking portion 31 before processing the first shot region. Then, in a step shown in FIG. 8, the mold driving mechanism 24 drives the mold M upward, separating the mold M from the solidified imprint material IM on the substrate S.

A method of bringing the mold into contact with the imprint material in each shot region of the plurality of shot regions on the substrate where the imprint material is arranged and curing it after the imprint material is arranged on all, or two or more shot regions has been described with reference to FIGS. 6A, 6B, 7A, 7B, and 8. This is merely an application of the present invention, and the present invention can also be applied to a method other than this method. The imprint apparatus 100 can also be applied to, for example, a method of arranging the spread accelerator on all, or two or more shot regions of the plurality of shot regions on the substrate, and then arranging the imprint material on the spread accelerator when the imprint process is performed on each shot region.

FIG. 10 exemplifies the order of the imprint process for the plurality of shot regions on the substrates. Note that each rectangle in the substrate S indicates the shot region. Symbols such as S1, S2, S3, and the like are given in order to distinguish the shot regions from each other. Note that the imprint process is performed in the order of shot regions S1, S2, S3 . . . . A case will be considered in which the imprint process for the shot regions S1 to S3 and shot regions S4 to S8 is terminated, and the imprint process is performed on a shot region S9. In this case, out of the shot regions adjacent to the shot region S9, the shot regions S2, S3, and S8 are shot regions where the imprint process has already been completed. It is therefore preferable that the periphery of each of the shot regions S2, S3, and S8 is also irradiated with light in the imprint process for the shot region S9. Alternatively, it is preferable that a region (to be referred to as a boundary region hereinafter) which includes a boundary between the shot region S9, and each of the shot regions S2, S3, and S8 is also irradiated with light. This is because if the imprint material IM in the periphery of each of the shot regions S2, S3, and S8 or the boundary region remains uncured, the uncured imprint material IM may flow or volatize, causing a pattern error in the subsequent process.

To prevent this, the controller 18 can be configured to decide the target irradiation region so as to partially irradiate, with light, the peripheries of the shot regions (the shot regions S2, S3, and S8 in the above-described example) that have already undergone the imprint process out of the peripheral shot regions of the shot region (the shot region S9 in the above-described example) to be imprinted and so as not to irradiate, with the light, the shot regions that have not yet undergone the imprint process out of the peripheral shot regions. As in this example, the controller 18 may be configured to decide the target irradiation region individually for each of the plurality of shot regions.

FIG. 11 schematically shows the arrangement of an imprint apparatus 100 according to the second embodiment of the present invention. Note that matters that are not mentioned in the second embodiment can comply with the first embodiment. In the second embodiment, a light blocking portion 31 is arranged between a mirror 16 and a mold holder 23, for example, between an optical system 21 and the mold holder 23. Alternatively, the light blocking portion 31 may be arranged between a mold driving mechanism 24 and the mold holder. With such an arrangement, the distance between the light blocking portion 31 and a mold M is short, reducing a blur at the boundary of an irradiation region caused by diffracting light from a light source 6 with the light blocking blade of the light blocking portion 31.

When the light blocking portion 31 is arranged between the mold M and a camera 15 (which is an image capture or an image capture device) as in FIG. 11, the camera 15 may capture the light blocking portion 31 directly. For example, the camera 15 captures an opening (an opening which defines the irradiation region) formed by light blocking blades 310 of the light blocking portion 31 and based on an image capture result, the position and shape of the opening are adjusted so as to fit a target irradiation region. The camera 15 may capture the light blocking portion 31 and the mold M (pattern region 110) simultaneously or separately.

FIG. 12 schematically shows the arrangement of an imprint apparatus 100 according to the third embodiment of the present invention. Note that matters that are not mentioned in the third embodiment can comply with the first embodiment. In the third embodiment, an arrangement is made such that light from a light source 6 enters an imprint material on a substrate S at an angle tilted with respect to the normal of the surface of the substrate S. With such an arrangement, a mirror 16 becomes unnecessary.

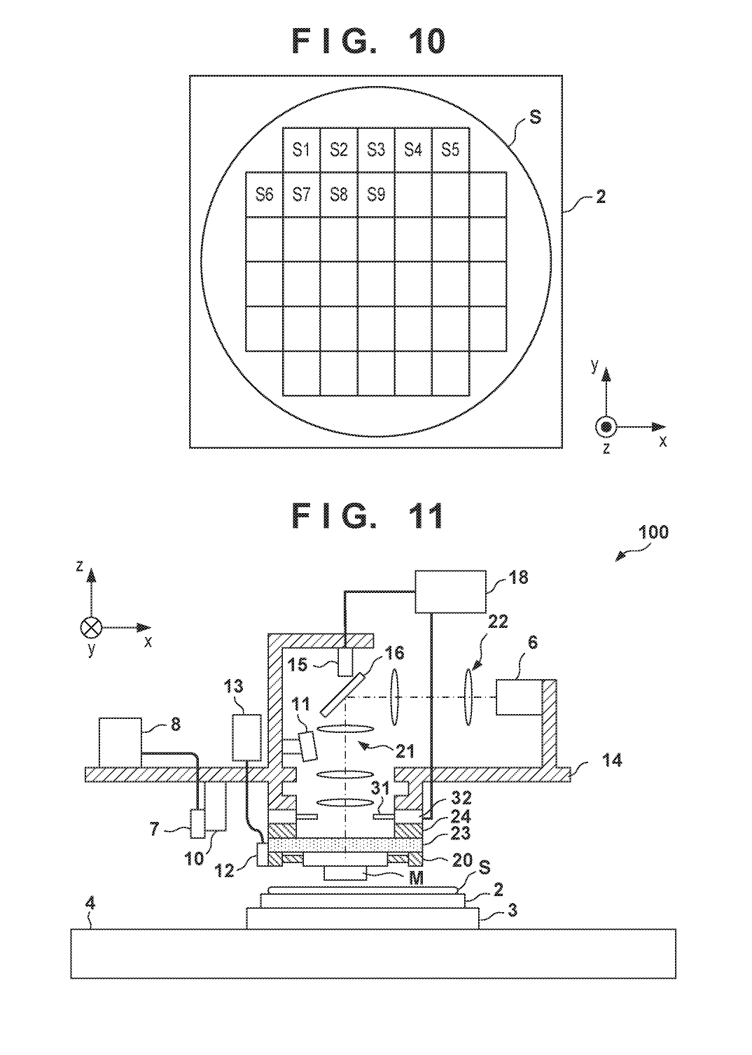

FIG. 13 schematically shows the arrangement of an imprint apparatus 100 according to the fourth embodiment of the present invention. Note that matters that are not mentioned in the fourth embodiment can comply with the first embodiment. In the fourth embodiment, a light source 6 is arranged such that the optical axis of light from the light source 6 between the light source 6 and a mold holder 23 is parallel to the normal of the surface of a substrate S. In the fourth embodiment, a camera 15 is arranged such that the optical axis of the camera 15 has an angle tilted with respect to the normal of the surface of the substrate S. Also in this arrangement, a mirror 16 becomes unnecessary.

FIG. 14 shows another arrangement example of a light blocking portion 31 and a driver 32 applied to the imprint apparatus 100 according to the first and fourth embodiments. In the arrangement example shown in FIG. 14, the light blocking portion 31 can include four light blocking blades 310 which are, respectively, arranged so as to define four sides of a rectangular irradiation region and a support plate 330. The driver 32 can include four first actuators 321 which, respectively, drive the four light blocking blades 310 translationally and a second actuator 323 which drives the support plate 330 rotationally. The support plate 330 has an opening OP larger than an opening (an opening which defines an irradiation region) formed by the light blocking blades 310, and also supports the four light blocking blades 310 and the four first actuators 321. The support plate 330 is pivotably supported by a base portion 340 and rotationally driven by the second actuator 323.

The four light blocking blades 310 need not be driven rotationally on an individual basis in a case in which a manufacturing error of a mold M held by the mold holder 23 is small, and the mold M includes an accurate rectangular pattern region. In this case, the second actuator 323 can rotationally drive the four light blocking blades 310 in a collective manner in accordance with a positioning error of the mold M with respect to the mold holder 23. With this arrangement example, it is possible to simplify the arrangement of a mechanism which adjusts the irradiation region.

A pattern of a cured product formed by using the imprint apparatus is used permanently for at least some of various articles or used temporarily when the various articles are manufactured. The article includes an electric circuit element, an optical element, a MEMS, a printing element, a sensor, a mold, or the like. The electric circuit element includes, for example, a volatile or nonvolatile semiconductor memory such as a DRAM, an SRAM, a flash memory, or an MRAM or a semiconductor element such as an LSI, a CCD, an image sensor, or an FPGA. The mold includes, for example, an imprinting mold.

The pattern of the cured product is used without any change as a constituent member of at least part of the above-described article or used temporarily as a resist mask. The resist mask is removed after etching, ion implantation, or the like is performed in a processing step of the substrate.

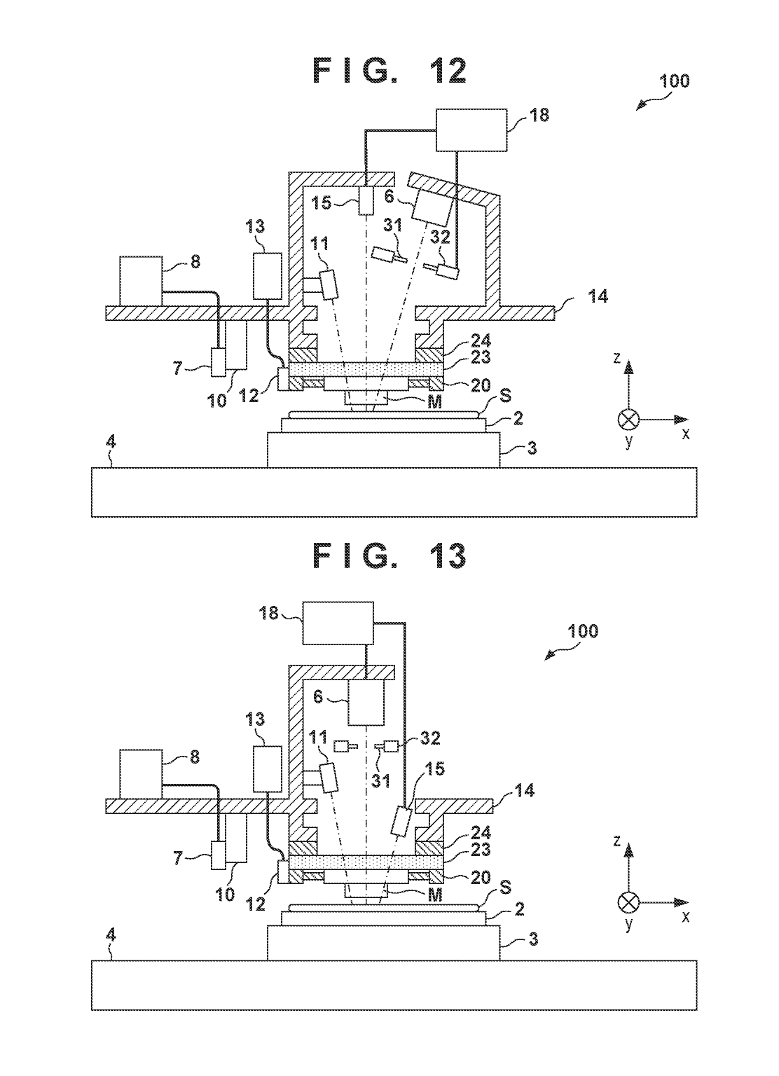

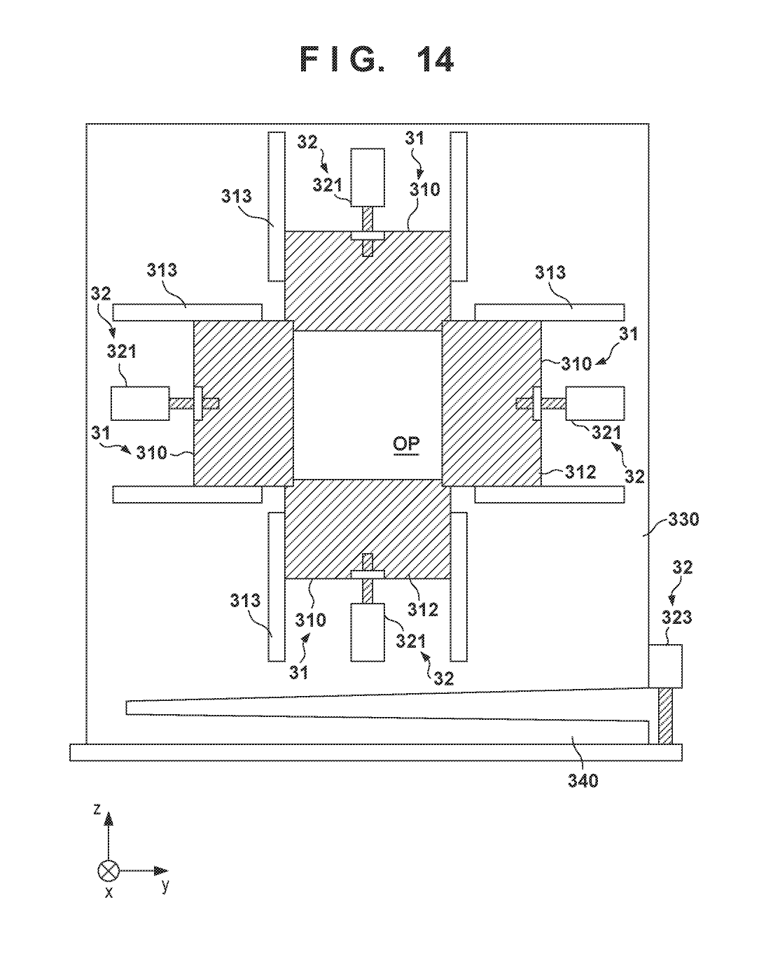

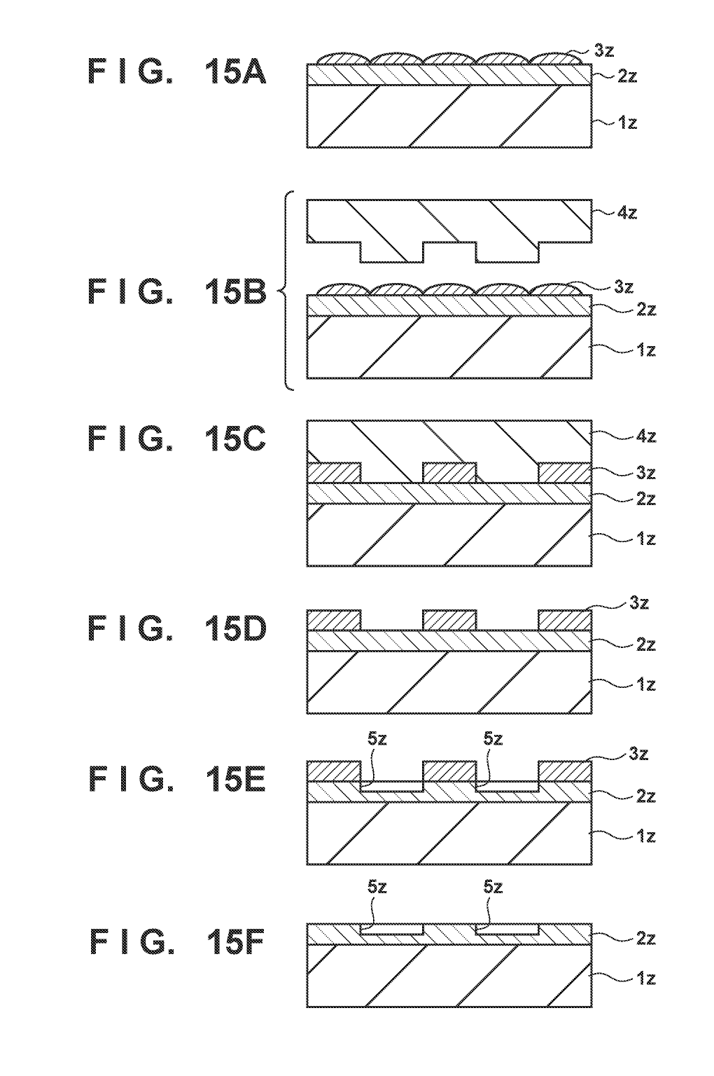

A detailed method of manufacturing the article will now be described. As shown FIG. 15A, a substrate 1z such as a silicon wafer having a processing target material 2z such as an insulator formed on its surface is prepared, and then an imprint material 3z is applied on the surface of the processing target material 2z by an inkjet method or the like. A state is shown here in which the imprint material 3z formed into a plurality of droplets is applied on the substrate.

As shown in FIG. 15B, a side of an imprinting mold 4z on which its three-dimensional pattern is formed faces the imprint material 3z on the substrate. As shown in FIG. 15C, a mold 4z and the substrate 1z to which the imprint material 3z is applied are brought into contact with each other, and a pressure is applied. The imprint material 3z fills the gap between the mold 4z and the processing target material 2z. The imprint material 3z is cured by irradiating it with light as curing energy through the mold 4z in this state.

As shown in FIG. 15D, the pattern of the cured product of the imprint material 3z is formed on the substrate 1z by releasing the mold 4z and the substrate 1z from each other after curing the imprint material 3z. The pattern of this cured product has a shape conforming to the concave portion of the mold corresponding to the convex portion of the cured product. That is, the three-dimensional pattern of the mold 4z is transferred to the imprint material 3z.

As shown in FIG. 15E, out of the surface of the processing target material 2z, portions without the cured product or portions where the cured products remain thin are removed and become trenches 5z by performing etching using the pattern of the cured product as an etching resistant mask. As shown in FIG. 15F, an article having the trenches 5z formed in the surface of the processing target material 2z can be obtained by removing the pattern of the cured product. The pattern of the cured product is removed here. However, the pattern of the cured product may be used as, for example, an interlayer dielectric film included in the semiconductor element or the like, that is, the constituent member of the article without removing it after processing.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2016-173125, filed Sep. 5, 2016, which is hereby incorporated by reference herein in its entirety.

What is claimed is:

1. An imprint apparatus which performs an imprint process of bringing a mold into contact with an imprint material on a substrate and curing the imprint material by light irradiation, the apparatus comprising:
a light source configured to emit light to irradiate the imprint material that is in contact with the mold;
a light blocking portion configured to define an irradiation region of the light emitted by the light source;
a driver configured to drive the light blocking portion;
an image capture having a field of view capable of capturing a region irradiated with the light emitted by the light source; and
a controller configured to generate, based on an image of the mold provided from the image capture, control information which controls driving of the light blocking portion by the driver.

2. The apparatus according to claim 1, wherein the controller generates the control information so as to irradiate a target irradiation region with the light emitted by the light source.

3. The apparatus according to claim 2, wherein the target irradiation region is a predetermined region of the mold.

4. The apparatus according to claim 3, wherein the mold includes a pattern region in which a pattern is formed and a peripheral region configured to surround the pattern region, and
the predetermined region as the target irradiation region is the pattern region.

5. The apparatus according to claim 2, further comprising a mold holder configured to hold the mold,
wherein the controller generates the control information based on an image captured by the image capture after the mold holder holds the mold and before the imprint process is performed on the substrate.

6. The apparatus according to claim 5, wherein the controller generates the control information based on an image obtained by capturing, with the image capture, the irradiation region defined by the light blocking portion.

7. The apparatus according to claim 2, wherein the substrate includes a plurality of shot regions, and
the target irradiation region is decided for each of the plurality of shot regions.

8. The apparatus according to claim 7, wherein the target irradiation region is decided so as to partially irradiate, with light, a periphery of a shot region that has already undergone the imprint process out of peripheral shot regions of a shot region to be imprinted and so as not to irradiate, with the light, a shot region that has not yet undergone the imprint process out of the peripheral shot regions.

9. The apparatus according to claim 1, wherein the light blocking portion includes a light blocking blade, and the driver includes a first actuator configured to drive the light blocking blade translationally and a second actuator configured to drive the light blocking blade rotationally.

10. The apparatus according to claim 1, wherein the light blocking portion includes four light blocking blades which are, respectively, arranged so as to define four sides of a rectangular irradiation region, and the driver includes four first actuators which are, respectively, configured to drive the four light blocking blades translationally and four second actuators which are, respectively, configured to drive the four light blocking blades rotationally.

11. The apparatus according to claim 9, wherein the light blocking blade includes a first portion and a second portion pivotably connected to the first portion, the first actuator is arranged so as to drive the first portion translationally, and the second actuator is arranged so as to drive the second portion rotationally.

12. The apparatus according to claim 11, wherein the light blocking portion further includes a linear guide configured to guide the first portion.

13. The apparatus according to claim 1, wherein the light blocking portion includes four light blocking blades which are, respectively, arranged so as to define four sides of a rectangular irradiation region and a support plate configured to support the four light blocking blades, and the driver includes four first actuators which are, respectively, configured to drive the four light blocking blades transnationally and a second actuator configured to drive the support plate rotationally.

14. The apparatus according to claim 1, wherein the controller observes a contact state between the mold and the imprint material on the substrate based on an image provided from the image capture.

15. The apparatus according to claim 1, further comprising a mirror configured to deflect a path of the light from the light source,
wherein the light blocking portion is arranged between the light source and the mirror.

16. The apparatus according to claim 1, further comprising a mirror configured to deflect a path of the light from the light source and a mold holder configured to hold the mold,
wherein the light blocking portion is arranged between the mirror and the mold holder.

17. The apparatus according to claim 1, wherein the light source is arranged such that the light from the light source enters the imprint material on the substrate at an angle tilted with respect to a normal of a surface of the substrate.

18. The apparatus according to claim 1, wherein the image capture is arranged such that an optical axis of the image capture has an angle tilted with respect to a normal of a surface of the substrate.

19. A method of manufacturing an article, the method comprising:
forming a pattern on a substrate by an imprint apparatus; and
processing the substrate on which the pattern has been formed in the forming,
wherein the article is manufactured from the processed substrate, and
wherein the imprint apparatus is configured to perform an imprint process of bringing a mold into contact with an imprint material on the substrate and curing the imprint material by light irradiation, the apparatus comprising:
a light source configured to emit light to irradiate the imprint material that is in contact with the mold;
a light blocking portion configured to define an irradiation region of the light emitted by the light source;
a driver configured to drive the light blocking portion;
an image capture having a field of view capable of capturing a region irradiated with the light emitted by the light source; and
a controller configured to generate, based on an image of the mold provided from the image capture, control information which controls driving of the light blocking portion by the driver.

20. An imprint apparatus which performs an imprint process of bringing a mold into contact with an imprint material on a substrate and curing the imprint material by light irradiation, the apparatus comprising:
a light source configured to emit light to irradiate the imprint material that is in contact with the mold;
a light blocking portion configured to define an irradiation region of the light emitted by the light source;
a driver configured to drive the light blocking portion;
an image capture having a field of view capable of capturing the light blocking portion; and
a controller configured to generate, based on an image of the light blocking portion and an image of the mold provided from the image capture, control information which controls driving of the light blocking portion by the driver.
